(19) United States
(12) Patent Application Publication
(10) Pub. No.: US 2025/0168478 A1
(43) Pub. Date: May 22, 2025

(54) CAMERA MODULE

(71) Applicant: Sharp Sensing Technology Corporation, Tenri City (JP)

(72) Inventors: SHOGO FURUKAWA, Tenri City (JP); SHINICHI TOKUNO, Tenri City (JP)

(21) Appl. No.: 18/951,384

(22) Filed: Nov. 18, 2024

(30) Foreign Application Priority Data
Nov. 22, 2023 (JP) 2023-198216

(51) Int. Cl. H04N 23/54; G03B 17/12; H04N 23/695; H05K 1/02

(52) U.S. Cl. CPC H04N 23/54; G03B 17/12; H04N 23/695; H05K 1/028

(57) ABSTRACT

A camera module includes: a lens; a holder holding the lens; a frame surrounding the holder; a driving mechanism configured to move the holder with respect to the frame; and a flexible printed circuit board provided with a connection portion connected to the holder, an attachment portion attached to the frame, and a tortuous portion being tortuous between the connection portion and the attachment portion.

### CROSS-REFERENCE TO RELATED APPLICATION

The present application claims priority from Japanese Application JP2023-198216, the content of which is hereby incorporated by reference into this application.

### BACKGROUND OF THE INVENTION

### 1. Field of the Invention

The present disclosure relates to a camera module.

### 2. Description of the Related Art

Japanese Unexamined Patent Application Publication No. 2022-163541 discloses an imaging device. In the imaging device, a module holder holds a camera module. In addition, a driving mechanism drives the module holder. This tilts the optical axis of the camera module with respect to its lens body. Further, the lower surface of a flexible printed circuit board is attached to the driving mechanism. Further, the front surface of the flexible printed circuit board extends upward from the front end of the lower surface of the flexible printed circuit board and is folded back to extend outside a housing (paragraphs 0009, 0017 and 0024).

### SUMMARY OF THE INVENTION

In the imaging device disclosed in Japanese Unexamined Patent Application Publication No. 2022-163541, the flexible printed circuit board may hinder the movement of the camera module.

The present disclosure has been made in view of this problem. One aspect of the present disclosure is directed to, for instance, providing a camera module having a flexible printed circuit board that does not hinder the movement of its holder holding the lens.

A camera module according to one aspect of the present disclosure is provided with the following: a lens; a holder holding the lens; a frame surrounding the holder; a driving mechanism configured to move the holder with respect to the frame; and a flexible printed circuit board provided with a connection portion connected to the holder, an attachment portion attached to the frame, and a tortuous portion being tortuous between the connection portion and the attachment portion.

### BRIEF DESCRIPTION OF THE DRAWINGS

FIG. 1 is a schematic perspective view of a camera module according to a first embodiment viewed from obliquely above;

FIG. 2 is a schematic perspective view of the camera module according to the first embodiment viewed from obliquely below;

FIG. 3 is a schematic exploded perspective view of the camera module according to the first embodiment viewed from obliquely above;

FIG. 4 is a schematic cross-sectional view of the camera module according to the first embodiment;

FIG. 5 is a schematic perspective view of a holder, a frame, and FPCs that are provided in the camera module according to the first embodiment and are viewed from obliquely below;

FIG. 6 is a schematic bottom view of the holder, frame, and FPCs, which are provided in the camera module according to the first embodiment;

FIG. 7 is a schematic perspective view of a driving mechanism provided in a tilt actuator provided in the camera module according to the first embodiment;

FIG. 8 is a schematic perspective view of a sensor unit, a shift actuator, and the tilt actuator that are provided in the camera module according to the first embodiment, with the sensor unit and shift actuator tilted in a +X-direction.

FIG. 9 is a schematic perspective view of the sensor unit, shift actuator, and tilt actuator, which are provided in the camera module according to the first embodiment, with the sensor unit and shift actuator tilted in a −X-direction.

FIG. 10 is a schematic bottom view of the holder, frame, and FPCs that are provided in a camera module according to a second embodiment; and

FIG. 11 is a schematic bottom view of the holder, frame, and FPCs that are provided in a camera module according to a third embodiment.

### DETAILED DESCRIPTION OF THE INVENTION

Embodiments of the present disclosure will be described with reference to the drawings.

It is noted that identical or equivalent elements will be denoted by the same signs throughout the drawings, and the description of redundancies will be omitted.

### 1 First Embodiment

### 1.1 Camera Module

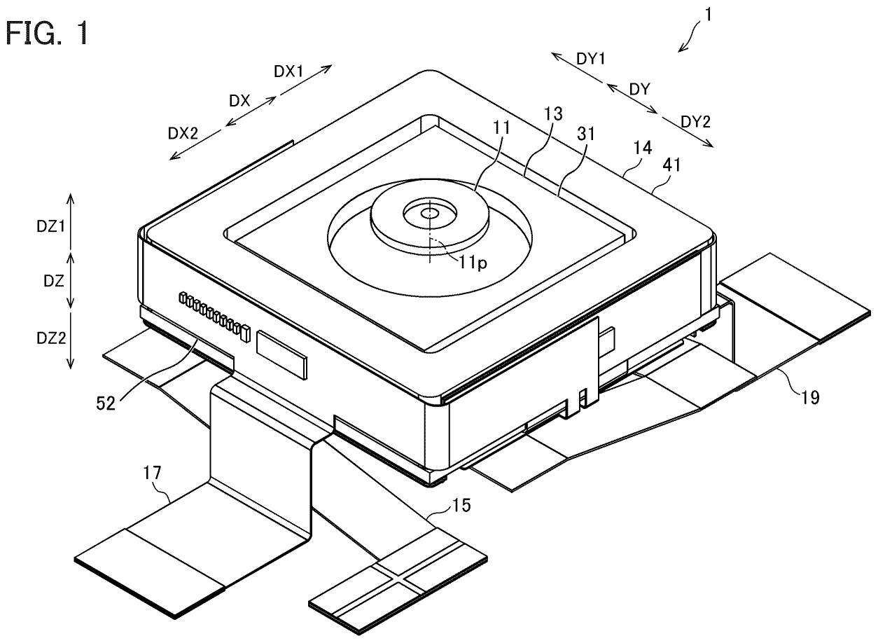

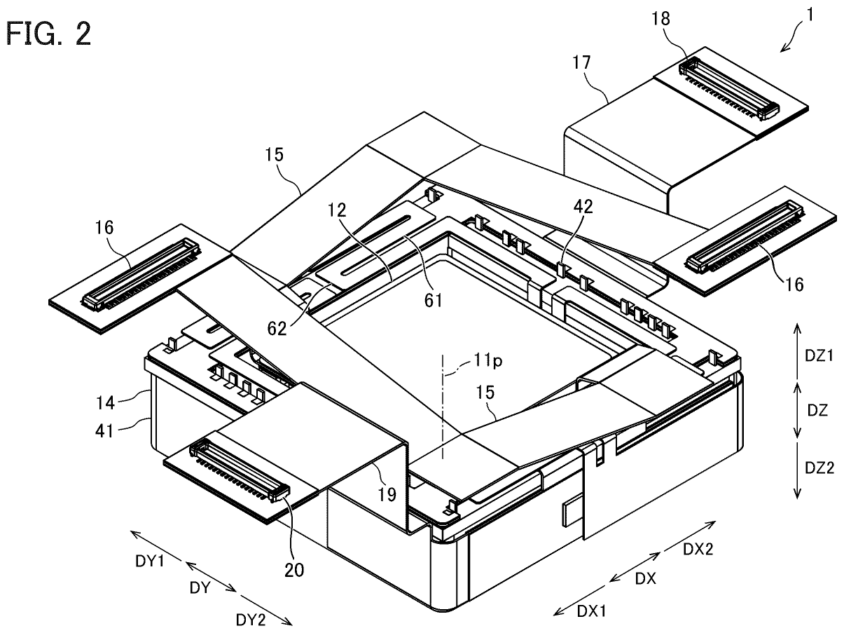

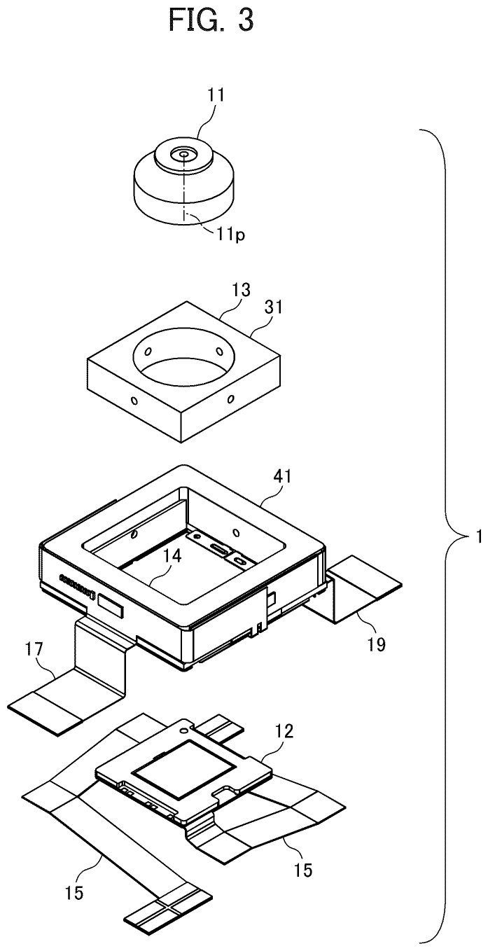

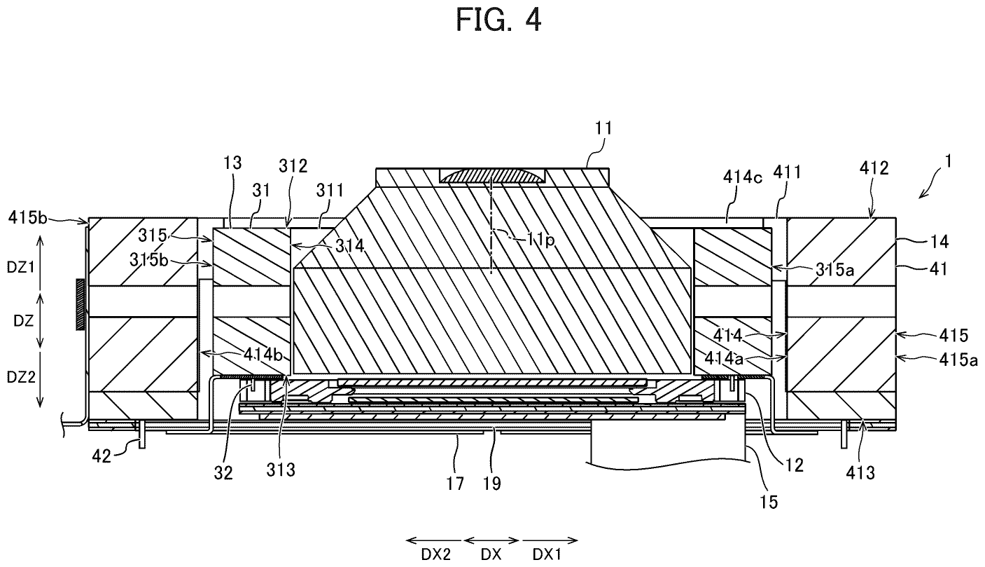

FIG. 1 is a schematic perspective view of a camera module according to a first embodiment viewed from obliquely above. FIG. 2 is a schematic perspective view of the camera module according to the first embodiment viewed from obliquely below. FIG. 3 is a schematic exploded perspective view of the camera module according to the first embodiment viewed from obliquely above. FIG. 4 is a schematic cross-sectional view of the camera module according to the first embodiment.

The camera module, 1, according to the first embodiment illustrated in FIGS. 1 to 4 is incorporated in a smartphone. The camera module 1 may be incorporated in a mobile communication terminal other than a smartphone. For instance, the camera module 1 may be incorporated in a feature phone, a tablet, or other things. The camera module 1 may be incorporated in an apparatus other than a mobile communication terminal.

The camera module 1 forms an image of an object, captures this formed object image and outputs an image signal corresponding to the captured object image.

As illustrated in FIGS. 1 to 4, the camera module 1 is provided with a lens 11, a sensor unit 12, a shift actuator 13, a tilt actuator 14, two flexible printed circuit boards (FPCs) 15, two connectors 16, an FPC 17, a connector 18, an FPC 19, and a connector 20.

The lens 11 concentrates light coming from an object onto the imaging surface of the sensor unit 12. The lens 11 accordingly forms an image of the object onto the imaging surface of the sensor unit 12. The lens 11 has an optical axis 11p.

Here, a Z-direction DZ is defined that is parallel to the optical axis 11p when the shift actuator 13 and a holder 31, which will be described later on, do not tilt; in addition, an X-direction DX and a Y-direction DY are defined that are perpendicular to the optical axis 11p when the shift actuator 13 and the holder 31, which will be described later on, do not tilt. The X-direction DX and the Y-direction DY are perpendicular to each other. Further, a +X-direction DX1, which is one direction of the X-direction DX, and a −X-direction DX2, which is the other direction of the X-direction DX are defined; in addition, a +Y-direction DY1, which is one direction of the Y-direction DY, and a −Y-direction DY2, which is the other direction of the Y-direction DY, are defined; in addition, a +Z-direction DZ1, which is one direction of the Z-direction DZ, and a-Z-direction DZ2, which is the other direction of the Z-direction DZ, are defined.

The sensor unit 12 operates using supplied electric power. The sensor unit 12 captures the object image formed on the imaging surface, in accordance with an input control signal. The sensor unit 12 outputs an image signal corresponding to the captured object image.

The sensor unit 12 is coupled to the shift actuator 13. Thus, the sensor unit 12 and the shift actuator 13 operate integrally.

The shift actuator 13 shifts the lens 11 in the X-direction DX, Y-direction DY, and Z-direction DZ in accordance with an input driving signal. This enables the camera module 1 to perform focusing and optical image stabilization.

The shift actuator 13 is movable without being fixed to, for instance, the housing of the smartphone in which the camera module 1 is incorporated.

The tilt actuator 14 tilts the shift actuator 13 from the Z-direction DZ to the X-direction DX and Y-direction DY in accordance with the input driving signal. The tilt actuator 14 thus tilts the sensor unit 12 and shift actuator 13 from the Z-direction DZ to the X-direction DX and Y-direction DY. This enables the camera module 1 to perform optical image stabilization.

The tilt actuator 14 is fixed to, for instance, the housing of the smartphone in which the camera module 1 is incorporated.

First ends of the two FPCs 15 are electrically and mechanically connected to the sensor unit 12. Second ends of the two FPCs 15 are electrically and mechanically connected to the respective two connectors 16. The FPCs 15 transmit electric power from the two connectors 16 to the sensor unit 12 and supplies the transmitted electric power to the sensor unit 12. The FPCs 15 transmit a control signal from the two connectors 16 to the sensor unit 12 and inputs the transmitted control signal to the sensor unit 12. The FPCs 15 transmit an output image signal from the sensor unit 12 to the two connectors 16.

The two FPCs 15 are easy to deform. This can prevent the two FPCs 15 from hindering the tilt of the sensor unit 12.

The two FPCs 15 are drawn from the sensor unit 12; this can prevent the FPCs 15 from hindering the tilt of the sensor unit 12 when compared with an instance where a single FPC 15 is drawn from the sensor unit 12.

The camera module 1 may be provided with three or more FPCs 15 and three or more connectors 16.

A first end of the FPC 17 is electrically and mechanically connected to the shift actuator 13. A second end of the FPC 17 is electrically and mechanically connected to the connector 18. The FPC 17 transmits a driving signal from the connector 18 to the shift actuator 13 and inputs the transmitted driving signal to the shift actuator 13.

The FPC 17 can be deformed easily. This can prevent the FPC 17 from hindering the tilt of the shift actuator 13.

A first end of the FPC 19 is electrically and mechanically connected to the tilt actuator 14. A second end of the FPC 19 is electrically and mechanically connected to the connector 20. The FPC 19 transmits a driving signal from the connector 20 to the tilt actuator 14 and inputs the transmitted driving signal to the tilt actuator 14.

The two connectors 16, the connector 18, and the connector 20 are electrically and mechanically connected to the connector of the smartphone in which the camera module 1 is incorporated.

Four FPCs consisting of the two FPCs 15, FPC 17, and FPC 19 are drawn from the camera module 1.

### 1.2 Shift Actuator

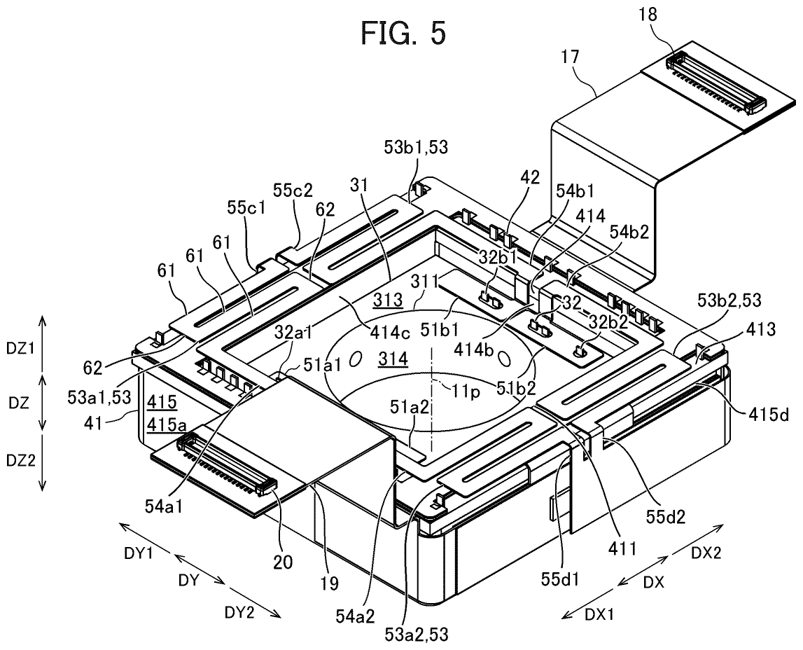

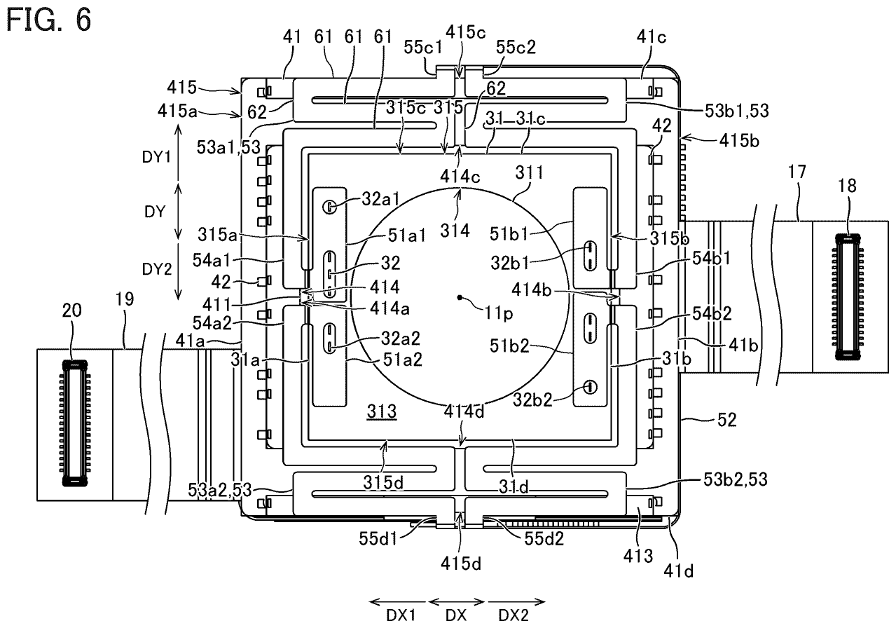

FIG. 5 is a schematic perspective view of the holder, frame, and FPCs, which are provided in the camera module according to the first embodiment, viewed from obliquely below. FIG. 6 is a schematic bottom view of the holder, frame, and FPCs, which are provided in the camera module according to the first embodiment.

As illustrated in FIG. 1 and FIGS. 3 to 6, the shift actuator 13 is provided with the holder 31 and a plurality of energization pins 32. The shift actuator 13 is provided with a driving mechanism, which is not shown.

The holder 13 constitutes a movable portion not being fixed to, but not limited to, the housing of the smartphone in which the camera module 1 is incorporated.

The holder 31 is shaped in a rectangular parallelepiped with a hole. The holder 31 thus has a hole 311, as illustrated in FIGS. 4 to 6. The hole 311 is a circular hole. The hole 311 houses the lens 11. The holder 31 holds the lens 11 housed in the hole 311.

As illustrated in FIGS. 4 to 6, the holder 31 has an upper surface 312, a lower surface 313, an inner periphery surface 314, and an outer periphery surface 315.

The upper surface 312 and lower surface 313 of the holder 31 are perpendicular to the Z-direction DZ, are away from each other in the Z-direction DZ and respectively faces toward the +Z-direction DZ1 and the −Z-direction DZ2.

The inner periphery surface 314 of the holder 31 extends from the inner periphery of the upper surface 312 of the holder 31 to the inner periphery of the lower surface 313 of the holder 31. The inner periphery surface 314 is a circumferential surface having a central axis coincident with the optical axis 11p. The inner periphery surface 314 defines the hole 311 of the holder 31.

The outer periphery surface 315 of the holder 31 extends from the outer periphery of the upper surface 312 of the holder 31 to the outer periphery of the lower surface 313 of the holder 31.

As illustrated in FIGS. 4 and 6, the outer periphery surface 315 of the holder 31 has a first surface 315a, a second surface 315b, a third surface 315c, and a fourth surface 315d. The first surface 315a and the second surface 315b are perpendicular to the X-direction DX, are respectively away from the optical axis 11p in the +X-direction DX1 and the −X-direction DX2 and respectively face toward the +X-direction DX1 and the −X-direction DX2. The third surface 315c and the fourth surface 315d are perpendicular to the Y-direction DY, are respectively away from the optical axis 11p in the +Y-direction DY1 and the −Y-direction DY2 and respectively face toward the +Y-direction DY1 and the −Y-direction DY2.

As illustrated in FIG. 6, the holder 31 has a square outline shape in a plan view from the −Z-direction DZ2. This square outline shape has a first side 31a, a second side 31b, a third side 31c, and a fourth side 31d.

The first side 31a and second side 31b of the holder 31 are perpendicular to the X-direction DX, are respectively away from the optical axis 11p in the +X-direction DX1 and the −X-direction DX2 by the same distance and face each other. The third side 31c and fourth side 31d of the holder 31 are perpendicular to the Y-direction DY, are respectively away from the optical axis 11p in the +Y-direction DY1 and the −Y-direction DY2 by the same distance and face each other. The holder 31 may have an outline shape other than a square outline shape.

Each of the plurality of energization pins 32 is provided with a buried portion and a projecting portion. The buried portion is buried in the holder 31. The projecting portion projects from the lower surface 313 of the holder 31 toward the −Z-direction DZ2.

The plurality of energization pins 32 are electrically connected to the driving mechanism provided in the shift actuator, and to the first end of the FPC 17. This can supply a driving signal transmitted by the FPC 17 to the driving mechanism provided in the shift actuator.

As illustrated in FIGS. 5 and 6, the plurality of energization pins 32 include first energization pins 32a1 and 32a2, and second energization pins 32b1 and 32b2. The first energization pins 32a1 and 32a2 are arranged along the first side 31a of the holder 31. The second energization pins 32b1 and 32b2 are arranged along the second side 31b of the holder 31.

The driving mechanism provided in the shift actuator drives the lens 11 in accordance with the supplied driving signal. Accordingly, the shift actuator 13 shifts the lens 11.

The driving mechanism provided in the shift actuator is a voice coil motor. The driving mechanism may be a driving mechanism other than a voice coil motor.

### 1.3 Tilt Actuator

As illustrated in FIGS. 1 to 6, the tilt actuator 14 is provided with a frame 41 and a plurality of energization pins 42. The tilt actuator 14 is provided with a driving mechanism, which is not shown.

The frame 14 constitutes a fixed portion fixed to, but not limited to, the housing of the smartphone in which the camera module 1 is incorporated.

The frame 41 has a square shape. The frame 41 thus has a hole 411, as illustrated in FIGS. 4 to 6. The hole 411 is a square hole. The hole 411 houses the shift actuator 13. The frame 41 thus surrounds the shift actuator 13. The frame 41 thus surrounds the holder 31 provided in the shift actuator 13.

As illustrated in FIGS. 4 to 6, the frame 41 has an upper end surface 412, a lower end surface 413, an inner periphery surface 414, and an outer periphery surface 415.

The upper end surface 412 and lower end surface 413 of the frame 41 are perpendicular to the Z-direction DZ, are away from each other in the Z-direction DZ and respectively faces toward the +Z-direction DZ1 and the −Z-direction DZ2.

The inner periphery surface 414 of the frame 41 extends from the inner periphery of the upper end surface 412 of the frame 41 to the inner periphery of the lower end surface 413 of the frame 41. The inner periphery surface 414 defines the hole 411 of the frame 41.

As illustrated in FIGS. 4 to 6, the inner periphery surface 414 of the frame 41 has a first surface 414a, a second surface 414b, a third surface 414c, and a fourth surface 414d.

The first surface 414a and second surface 414b of the frame 41 are perpendicular to the X-direction DX, are respectively away from the optical axis 11p in the +X-direction DX1 and the −X-direction DX2 and respectively face toward the −X-direction DX2 and the +X-direction DX1. The third surface 414c and fourth surface 414d of the frame 41 are perpendicular to the Y-direction DY, are respectively away from the optical axis 11p in the +Y-direction DY1 and −Y-direction DY2 and respectively face toward the −Y-direction DY2 and the +Y-direction DY1. The first surface 414a, second surface 414b, third surface 414c, and fourth surface 414d respectively face the first surface 315a, second surface 315b, third surface 315c, and fourth surface 315d of the outer periphery surface 315 of the holder 31 with clearances interposed therebetween.

The outer periphery surface 415 of the frame 41 extends from the outer periphery of the upper end surface 412 of the frame 41 to the outer periphery of the lower end surface 413 of the frame 41.

As illustrated in FIGS. 4 to 6, the outer periphery surface 415 has a first surface 415a, a second surface 415b, a third surface 415c, and a fourth surface 415d. The first surface 415a and the second surface 415b are perpendicular to the X-direction DX, are respectively away from the optical axis 11p in the +X-direction DX1 and the −X-direction DX2 and respectively face toward the +X-direction DX1 and the −X-direction DX2. The third surface 415c and the fourth surface 415d are perpendicular to the Y-direction DY, are respectively away from the optical axis 11p in the +Y-direction DY1 and the −Y-direction DY2 and respectively face toward the +Y-direction DY1 and the −Y-direction DY2.

As illustrated in FIG. 6, the frame 41 has a square outline shape in a plan view from the −Z-direction DZ2. This square outline shape has a first side 41a, a second side 41b, a third side 41c, and a fourth side 41d.

The first side 41a and second side 41b of the frame 41 are perpendicular to the X-direction DX, are respectively away from the optical axis 11p in the +X-direction DX1 and the −X-direction DX2 by the same distance and face each other. The third side 41c and fourth side 41d of the frame 41 are perpendicular to the Y-direction DY, are respectively away from the optical axis 11p in the +Y-direction DY1 and the −Y-direction DY2 by the same distance and face each other. The frame 41 may have an outline shape other than a square outline shape.

Each of the plurality of energization pins 42 is provided with a buried portion and a projection portion. The buried portion is buried in the frame 41. The projecting portion projects from the lower end surface 413 of the frame 41 toward the −Z-direction DZ2.

The plurality of energization pins 42 are electrically connected to the driving mechanism provided in the tilt actuator, and to the first end of the FPC 19. This can supply a driving signal transmitted by the FPC 19 to the driving mechanism provided in the tilt actuator.

The driving mechanism provided in the tilt actuator drives the shift actuator 13 in accordance with the supplied driving signal. Accordingly, the tilt actuator 14 tilts the shift actuator 13.

The driving mechanism provided in the tilt actuator may be any driving mechanism; an example is a shape memory alloy (SMA) wire actuator. The driving mechanism may be a driving mechanism other than an SMA wire actuator.

1.4 Insertion of Tortuous Portion between Connection Portion and Attachment Portion in FPC As illustrated in FIGS. 5 and 6, the FPC17 is provided with first connection portions 51a1 and 51a2, second connection portions 51b1 and 51b2, an attachment portion 52, first tortuous portions 53a1 and 53a2, and second tortuous portions 53b1 and 53b2.

The first connection portions 51a1 and 51a2 and the second connection portions 51b1 and 51b2 are connected to the holder 31. The attachment portion 52 is attached to the frame 41. Accordingly, the holder 31 is connected to the frame 41 via the FPC17. The FPC 17 can be deformed. Accordingly, the holder 31 is supported by the FPC17 while being able to undergo relative displacement with respect to the frame 41.

The first tortuous portion 53a1 is between the first connection portion 51a1 and the attachment portion 52. The first tortuous portion 53a2 is between the first connection portion 51a2 and the attachment portion 52. The second tortuous portion 53b1 is between the second connection portion 51b1 and the attachment portion 52. The second tortuous portion 53b2 is between the second connection portion 51b2 and the attachment portion 52.

Each tortuous portion 53 included in the first tortuous portions 53a1 and 53a2 and second tortuous portions 53b1 and 53b2 is tortuous. Accordingly, each tortuous portion 53 can be deformed easily. Accordingly, the FPC 17 can be deformed easily in accordance with the movement of the holder 31 with respect to the frame 41. This can prevent the FPC 17 from hindering the movement of the holder 31. This enables the tilt actuator 14 to move the shift actuator 13 with a small thrust.

The first tortuous portions 53a1 and 53a2 and the second tortuous portions 53b1 and 53b2 are disposed inside the outer periphery surface 415 of the frame 41 in the diameter direction. This can prevent a situation in which the camera module 1 is difficult to handle due to extension of the first tortuous portions 53a1 and 53a2 and second tortuous portions 53b1 and 53b2 out of the frame 41. This can prevent the first tortuous portions 53a1 and 53a2 and second tortuous portions 53b1 and 53b2 from degrading the commodity value of the camera module 1.

Each of the tortuous portions 53 desirably has a line width of 1.0 to 1.2 mm inclusive, and a thickness of 75 to 125 μm inclusive.

1.5 Symmetry of FPC's Drawing from Holder

As illustrated in FIGS. 5 and 6, the FPC17 is provided with first leader portions 54a1 and 54a2, and second leader portions 54b1 and 54b2.

The first leader portion 54a1 is between the first connection portion 51a1 and the first tortuous portion 53a1. The first leader portion 54a2 is between the first connection portion 51a2 and the first tortuous portion 53a2. The second leader portion 54b1 is between the second connection portion 51b1 and the second tortuous portion 53b1. The second leader portion 54b2 is between the second connection portion 51b2 and the second tortuous portion 53b2.

The first connection portions 51a1 and 51a2 are arranged along the first side 31a of the holder 31. The second connection portions 51b1 and 51b2 are arranged along the second side 31b of the holder 31.

The first leader portions 54a1 and 54a2 are connected to the first connection portions 51a1 and 51a2, respectively, and are drawn from the first side 31a of the holder 31. The first leader portions 54a1 and 54a2 are drawn from the first side 31a so as to extend from a region inside the first side 31a in the diameter direction astride the first side 31a to a region outside the first side 31a in the diameter direction. The second leader portions 54b1 and 54b2 are connected to the second connection portions 51b1 and 51b2, respectively, and are drawn from the second side 31b of the holder 31. The second leader portions 54b1 and 54b2 are drawn from the second side 31b so as to extend from a region inside the second side 31b in the diameter direction astride the second side 31b to a region outside the second side 31b in the diameter direction.

The first leader portion 54a1 and second leader portion 54b1 are respectively drawn from the first side 31a and second side 31b of the holder 31, which are a first opposed side and a second opposed side facing each other. The first leader portion 54a2 and second leader portion 54b2 are respectively drawn from the first side 31a and second side 31b of the holder 31, which are the first opposed side and the second opposed side facing each other. Accordingly, the FPC 17 can be drawn from the holder 31 toward the X-direction DX with high symmetry. This can increase the symmetry of a reaction force in the X-direction DX generated by the FPC 17.

### 1.6 Symmetry of FPC's Planer Shape

As illustrated in FIG. 6, the second connection portions 51b1 and 51b2, the second leader portions 54b1 and 54b2, and the second tortuous portions 53b1 and 53b2 each have a planer shape symmetrical to a corresponding one of the planer shape of the first connection portions 51a1 and 51a2, the planer shape of the first leader portions 54a1 and 54a2, and the planer shape of the first tortuous portions 53a1 and 53a2 about a YZ plane including the optical axis 11p. This can increase the symmetry of the reaction force in the X-direction DX generated by the FPC 17.

The first connection portions 51a2, the first leader portion 54a2, and the first tortuous portions 53a2, the second connection portion 51b2, the second leader portion 54b2, and the second tortuous portion 53b2 each have a planer shape symmetrical to a corresponding one of the planer shape of the first connection portion 51a1, the planer shape of the first leader portion 54a1, the planer shape of the first tortuous portion 53a1, the planer shape of the second connection portion 51b1, the planer shape of the second leader portion 54b1, and the planer shape of the second tortuous portion 53b1 about an XZ plane including the optical axis 11p. This can increase the symmetry of a reaction force in the Y-direction DY generated by the FPC 17.

1.7 Relationship between FPC's Drawing from Holder and FPC's Drawing from Frame

As illustrated in FIGS. 5 and 6, the FPC17 is provided with first leader portions 55cl and 55d1, and second leader portions 55c2 and 55d2.

The first leader portion 55cl is between the attachment portion 52 and the first tortuous portion 53a1. The first leader portion 55d1 is between the attachment portion 52 and the first tortuous portion 53a2. The second leader portion 55c2 is between the attachment portion 52 and the second tortuous portion 53b1. The second leader portion 55d2 is between the attachment portion 52 and the second tortuous portion 53b2.

The first tortuous portion 53a1 and the second tortuous portion 53b1 are arranged along the third side 41c of the frame 41. The first tortuous portion 53a2 and the second tortuous portion 53b2 are arranged along the fourth side 41d of the frame 41.

The first leader portion 55cl and the second leader portion 55c2 are connected to the first tortuous portion 53a1 and the second tortuous portion 53b1, respectively, and are drawn from the third side 41c of the frame 41. The first leader portion 55cl and the second leader portion 55c2 are drawn from the third side 41c so as to extend from a region inside the third side 41c in the diameter direction astride the third side 41c to a region outside the third side 41c in the diameter direction. The first leader portion 55d1 and the second leader portion 55d2 are connected to the first tortuous portion 53a2 and the second tortuous portion 53b2, respectively, and are drawn from the fourth side 41d of the frame 41. The first leader portion 55d1 and the second leader portion 55d2 are drawn from the fourth side 41d so as to extend from a region inside the fourth side 41d in the diameter direction astride the fourth side 41d to a region outside the fourth side 41d in the diameter direction.

The first side 31a of the holder 31 and the third side 41c of the frame 41, from which the first leader portion 54a1 and the first leader portion 55cl are respectively drawn, are a first side and a second side that are distant from the optical axis 11p toward the +X-direction DX1 and the +Y-direction DY1, which are a first direction and a second direction perpendicular to each other. The second side 31b of the holder 31 and the third side 41c of the frame 41, from which the second leader portion 54b1 and the second leader portion 55c2 are respectively drawn, are a first side and a second side that are distant from the optical axis 11p toward the −X-direction DX2 and the +Y-direction DY1, which are a first direction and a second direction perpendicular to each other. The first side 31a of the holder 31 and the fourth side 41d of the frame 41, from which the first leader portion 54a2 and the first leader portion 55d1 are respectively drawn, are a first side and a second side that are distant from the optical axis 11p toward the +X-direction DX1 and the −Y-direction DY2, which are a first direction and a second direction perpendicular to each other. The second side 31b of the holder 31 and the fourth side 41d of the frame 41, from which the second leader portion 54b2 and the second leader portion 55d2 are respectively drawn, are a first side and a second side that are distant from the optical axis 11p toward the −X-direction DX2 and the −Y-direction DY2, which are a first direction and a second direction perpendicular to each other. Accordingly, long sections can be achieved from the first leader portion 54a1 to the first leader portion 55cl, from the first leader portion 54a2 to the first leader portion 55d1, from the second leader portion 54b1 to the second leader portion 55c2, and from the second leader portion 54b2 to the second leader portion 55d2. This enables these sections to be deformed easily.

### 1.8 Surface Where Connection Portions, Tortuous Portions, and Attachment Portion Are Disposed

As illustrated in FIGS. 5 and 6, the first connection portions 51a1 and 51a2 and the second connection portions 51b1 and 51b2 are disposed on the lower surface 313 of the holder 31, which faces toward the −Z-direction DZ2, and are connected to the lower surface 313. The first tortuous portions 53a1 and 53a2 and the second tortuous portions 53b1 and 53b2 are disposed on the lower end surface 413 of the frame 41, which faces toward the −Z-direction DZ2. The first tortuous portions 53a1 and 53a2 and the second tortuous portions 53b1 and 53b2 are not fixed to the lower end surface 413 and can be thus deformed on the lower end surface 413.

In this way, placing the first connection portions 51a1 and 51a2, the second connection portions 51b1 and 51b2, the first tortuous portions 53a1 and 53a2, and the second tortuous portions 53b1 and 53b2 onto a surface such that these portions face toward the same direction can reduce bends in the sections from the first connection portion 51a1 to the first tortuous portion 53al, from the first connection portion 51a2 to the first tortuous portion 53a2, from the second connection portion 51b1 to the second tortuous portion 53b1, and from the second connection portion 51b2 to the second tortuous portion 53b2. This enables these sections to be deformed easily.

The attachment portion 52 is attached to the outer periphery surface 415 of the frame 41.

### 1.9 Planer Shapes of Tortuous Portions

As illustrated in FIGS. 5 and 6, each of the tortuous portions 53 included in the first tortuous portions 53a1 and 53a2 and second tortuous portions 53b1 and 53b2 is provided with a plurality of liner portions 61 and one or more folding-back portions 62.

The plurality of liner portions 61 provided in each of the first tortuous portion 53a1 and second tortuous portion 53b1, which are arranged along the third side 41c of the frame 41, extend parallel to the third side 41c. The plurality of liner portions 61 provided in each of the first tortuous portion 53a2 and second tortuous portion 53b2, which are arranged along the fourth side 41d of the frame 41, extend parallel to the fourth side 41d.

Each of the one or more of the folding-back portions 62 connects together two ends of respective two liner portions 61 adjacent to each other among the plurality of liner portions 61.

Accordingly, each tortuous portion 53 can have a zigzag shape. The foregoing can reduce the moment necessary for tilting the shift actuator 13.

### 1.10 Folded Structure

As illustrated in FIGS. 5 and 6, the first connection portions 51a1 has a straight-line shape extending in the −Y-direction DY2, which is parallel to the first side 31a of the holder 31. The first leader portion 54a1 has an L-shape extending in the +X direction DX1, which is perpendicular to the first side 31a, straddling the first side 31a, and then extending in the +Y direction DY1, which is parallel to the first side 31a, over the clearance between the first surface 315a of the outer periphery surface 315 of the holder 31 and the first surface 414a of the inner periphery surface 414 of the frame 41. Accordingly, the first connection portion 51a1 and the first leader portion 54al form a folded structure having a U-shape.

Likewise, the first connection portion 51a2 and the first leader portion 54a2 form a folded structure having a U-shape. In addition, the second connection portion 51b1 and the second leader portion 54b1 form a folded structure having a U-shape. In addition, the second connection portion 51b2 and the second leader portion 54b2 form a folded structure having a U-shape.

### 1.11 Driving Mechanism Provided in Tilt Actuator

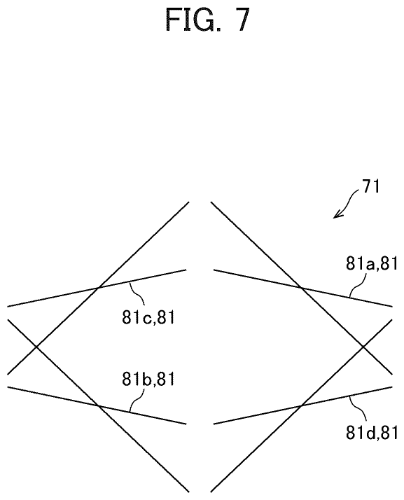

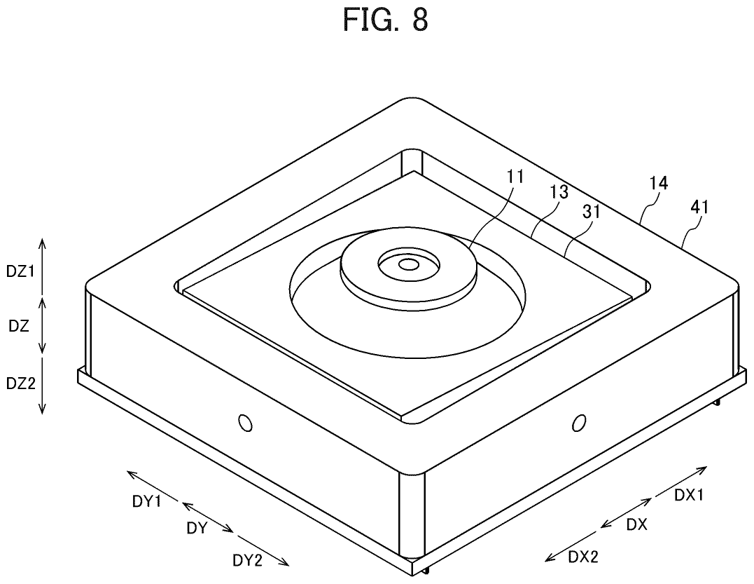

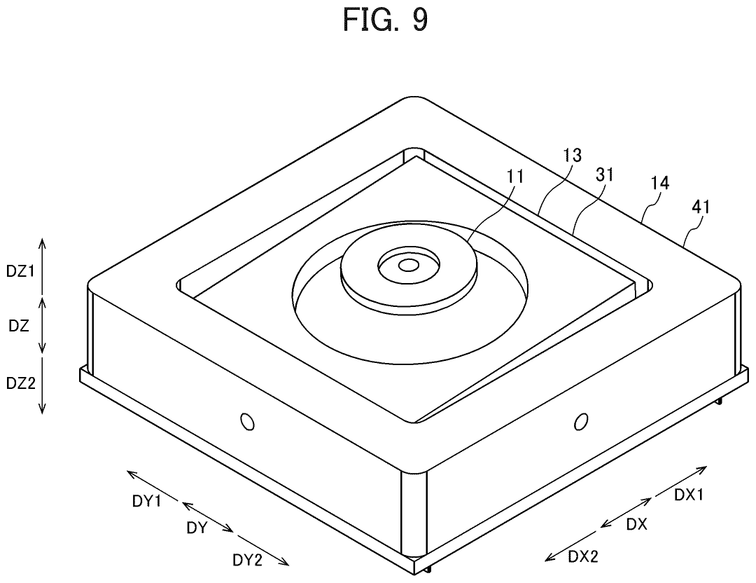

FIG. 7 is a schematic perspective view of a driving mechanism provided in a tilt actuator provided in the camera module according to the first embodiment. FIG. 8 is a schematic perspective view of a sensor unit, a shift actuator, and the tilt actuator that are provided in the camera module according to the first embodiment, with the sensor unit and shift actuator tilted in a +X-direction. FIG. 9 is a schematic perspective view of the sensor unit, shift actuator, and tilt actuator, which are provided in the camera module according to the first embodiment, with the sensor unit and shift actuator tilted in a −X-direction.

The SMA wire actuator is provided with the driving mechanism, 71, illustrated in FIG. 7. The driving mechanism 71 is provided with a first SMA wire pair 81a, a second SMA wire pair 81b, a third SMA wire pair 81c, and a fourth SMA wire pair 81d respectively facing the first side 31a, second side 31b, third side 31c, and fourth side 31d of the holder 31. The two SMA wires provided in each of SMA wire pairs 81 included in the first SMA wire pair 81a, the second SMA wire pair 81b, the third SMA wire pair 81c, and the fourth SMA wire pair 81d intersect with each other. One end of each of the two SMA wires is connected to the holder 31. The other end of each of the two SMA wires is connected to the frame 41. The two SMA wires expand and contract in response to a supplied driving signal. Accordingly, the driving mechanism 71 drives the holder 31 with respect to the frame 41 in accordance with the supplied driving signal. For instance, the driving mechanism 71 tilts the holder 31 in the +X-direction DX1 as illustrated in FIG. 8 and tilts the holder 31 in the −X-direction DX2 as illustrated in FIG. 9.

### 2 Second Embodiment

The following describes a point in which the second embodiment is different from the first embodiment. With regard to what will not be described, a configuration similar to the configuration used in the first embodiment will be used in the second embodiment as well.

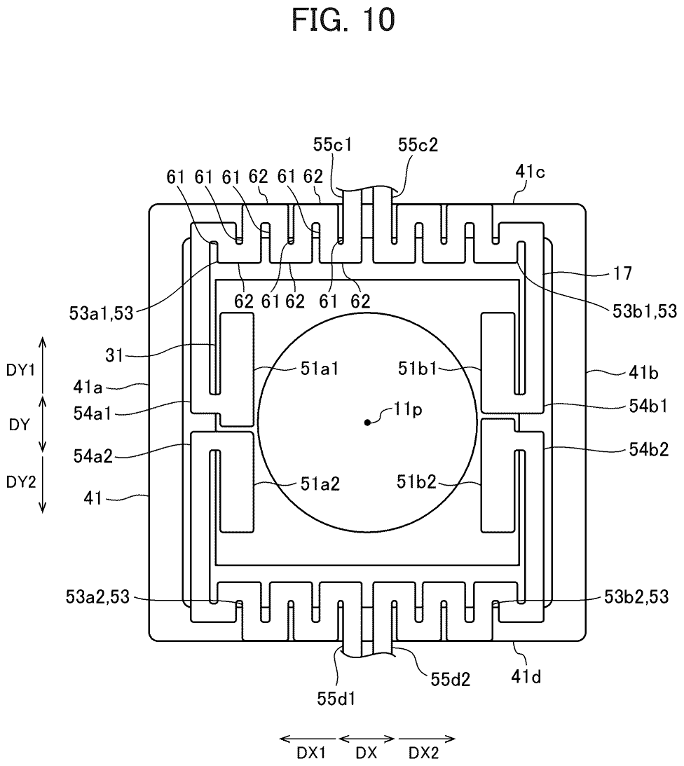

FIG. 10 is a schematic bottom view of the holder, frame, and FPCs that are included in a camera module according to the second embodiment.

In the second embodiment, the plurality of liner portions 61 provided in each of the first tortuous portion 53a1 and second tortuous portion 53b1, which are arranged along the third side 41c of the frame 41, extend perpendicularly to the third side 41c, as illustrated in FIG. 10. In addition, the plurality of liner portions 61 provided in each of the first tortuous portion 53a2 and second tortuous portion 53b2, which are arranged along the fourth side 41d of the frame 41, extend perpendicularly to the fourth side 41d.

The moment necessary for tilting the shift actuator 13 can be reduced in the second embodiment as well.

### 3 Third Embodiment

The following describes a point in which the third embodiment is different from the first embodiment. With regard to what will not be described, a configuration similar to the configuration used in the first embodiment will be used in the third embodiment as well.

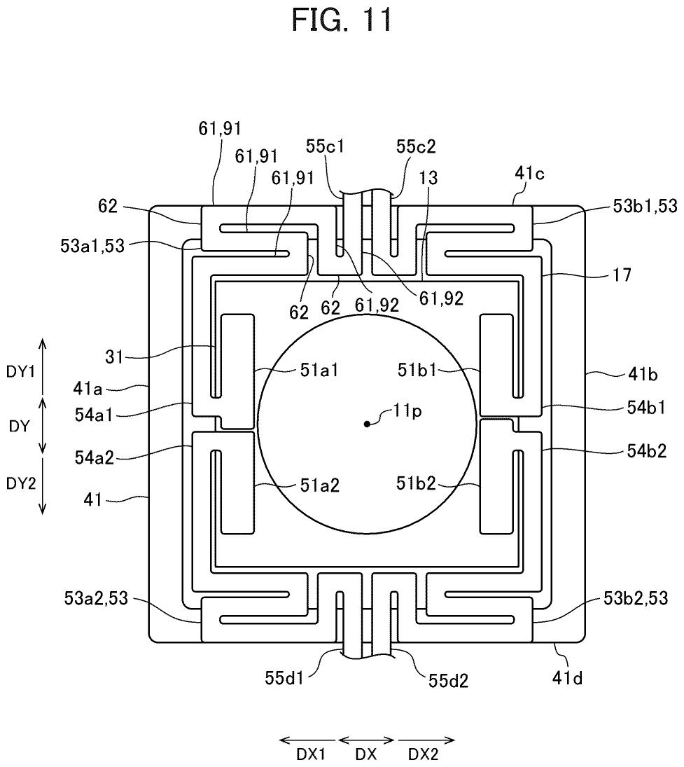

FIG. 11 is a schematic bottom view of the holder, frame, and FPCs that are provided in a camera module according to the third embodiment.

In the third embodiment, the plurality of liner portions 61 include a plurality of first liner portions 91 and a plurality of second liner portions 92, as illustrated in FIG. 11.

The plurality of first liner portions 91 provided in each of the first tortuous portion 53al and second tortuous portion 53b1, which are arranged along the third side 41c of the frame 41, extend parallel to the third side 41c. The plurality of second liner portions 92 provided in each of the first tortuous portion 53a1 and second tortuous portion 53b1 extend perpendicularly to the third side 41c. The plurality of first liner portions 91 provided in each of the first tortuous portion 53a2 and second tortuous portion 53b2, which are arranged along the fourth side 41d of the frame 41, extend parallel to the fourth side 41d. The plurality of second liner portions 92 provided in each of the first tortuous portion 53a2 and second tortuous portion 53b2 extend perpendicularly to the fourth side 41d.

In the third embodiment, the ratio between the moment necessary for tilting the shift actuator 13 in the X-direction DX and the moment necessary for tilting the shift actuator 13 in the Y-direction DY can be regulated by regulating the ratio between the number of first liner portions 91 and the number of second liner portions 92.

The present disclosure is not limited to the above-described embodiments. The present disclosure may be replaced with a configuration substantially identical to those described in the above-described embodiments, a configuration that provides the same action and effect as those described in the above-described embodiments, or a configuration that can achieve the same object as those described in the above-described embodiments.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A camera module comprising:
a lens;
a holder holding the lens;
a frame surrounding the holder;
a driving mechanism configured to move the holder with respect to the frame; and
a flexible printed circuit board provided with a connection portion connected to the holder, an attachment portion attached to the frame, and a tortuous portion being tortuous between the connection portion and the attachment portion.

2. The camera module according to claim 1, wherein
the frame has an outer periphery surface, and
the tortuous portion is disposed inside the outer periphery surface in a circumferential direction.

3. The camera module according to claim 1, wherein
the lens has an optical axis,
the connection portion is a first connection portion,
the tortuous portion is a first tortuous portion,
in a plan view from a direction parallel to the optical axis, the holder has an outline shape having a first opposed side and a second opposed side facing each other, and
the flexible printed circuit board is provided with a first leader portion disposed between the first connection portion and the first tortuous portion and drawn from the first opposed side, a second connection portion connected to the holder, a second tortuous portion being tortuous between the second connection portion and the attachment portion, and a second leader portion disposed between the second connection portion and the second tortuous portion and drawn from the second opposed side.

4. The camera module according to claim 3, wherein
the first connection portion is disposed along the first opposed side, and
the second connection portion is disposed along the second opposed side.

5. The camera module according to claim 3, wherein
the second connection portion, the second leader portion, and the second tortuous portion have a planer shape symmetrical to a planer shape of the first connection portion, the first leader portion, and the first tortuous portion about a plane including the optical axis.

6. The camera module according to claim 1, wherein
the lens has an optical axis,
in a plan view from a direction parallel to the optical axis, the holder has an outline shape having a first side distant from the optical axis toward a first direction,
in the plan view from the direction parallel to the optical axis, the frame has an outline shape having a second side distant from the optical axis toward a second direction perpendicular to the first direction, and
the flexible printed circuit board is provided with a leader portion disposed between the connection portion and the tortuous portion and drawn from the first side, and another leader portion disposed between the attachment portion and the tortuous portion and drawn from the second side.

7. The camera module according to claim 1, wherein
the lens has an optical axis,
the holder has a surface perpendicular to the optical axis,
the connection portion is connected to the surface,
the frame has an outer periphery surface, and an end surface perpendicular to the optical axis and facing toward a direction identical to a direction toward which the surface faces,
the tortuous portion is disposed on the end surface, and
the attachment portion is attached to the outer periphery surface.

8. The camera module according to claim 1, wherein
the tortuous portion has a liner shape having a line width of 1.0 to 1.2 mm inclusive, and a thickness of 75 to 125 μm inclusive.

9. The camera module according to claim 1, wherein
the lens has an optical axis,
in a plan view from a direction parallel to the optical axis, the frame has an outline shape having a side,
the tortuous portion is disposed along the side, and
the tortuous portion is provided with a plurality of liner portions extending parallel to the side.

10. The camera module according to claim 1, wherein
the lens has an optical axis,
in a plan view from a direction parallel to the optical axis, the frame has an outline shape having a side,
the tortuous portion is disposed along the side, and
the tortuous portion is provided with a plurality of liner portions extending perpendicularly to the side.

11. The camera module according to claim 1, wherein
the lens has an optical axis,
in a plan view from a direction parallel to the optical axis, the frame has an outline shape having a side,
the tortuous portion is disposed along the side, and
the tortuous portion is provided with a plurality of first liner portions extending parallel to the side, and a plurality of second liner portions extending perpendicularly to the side.
